(19) United States
(12) Patent Application Publication
(10) Pub. No.: US 2025/0266823 A1
(43) Pub. Date: Aug. 21, 2025

(54) SYSTEM-ON-CHIP FOR POWER MANAGEMENT IN MULTI-DIE STRUCTURE

(71) Applicant: Samsung Electronics Co., Ltd., Suwon-si (KR)

(72) Inventors: Taehong JANG, Suwon-si (KR); Sungcheol PARK, Suwon-si (KR); Jehyun PARK, Suwon-si (KR)

(73) Assignee: Samsung Electronics Co., Ltd., Suwon-si (KR)

(21) Appl. No.: 19/014,859

(22) Filed: Jan. 9, 2025

(30) Foreign Application Priority Data
Feb. 15, 2024 (KR) 10-2024-0021798
Apr. 11, 2024 (KR) 10-2024-0048933

(51) Int. Cl. H03K 17/20; H03K 19/0175; H03K 19/20

(52) U.S. Cl. CPC H03K 17/20; H03K 19/017545; H03K 19/20

(57) ABSTRACT

A system-on-chip (SoC) including a first die and a second die adjacent to a surface of the first die, the second die connected to the first die. The first die may include a first reset circuit configured to output a first reset signal to operate the first die based on a first voltage received from a power supply, and the second die may include a second reset circuit configured to output a second reset signal to operate the second die based on a second voltage received from the power supply.

### CROSS-REFERENCE TO RELATED APPLICATIONS

This U.S. non-provisional application claims priority under 35 USC § 119 to Korean Patent Application No. 10-2024-0021798, filed on Feb. 15, 2024, and Korean Patent Application No. 10-2024-0048933, filed on Apr. 11, 2024, in the Korean Intellectual Property Office, the entire contents of each of which are herein incorporated by reference in their entirety.

### BACKGROUND

Example embodiments relate to a system-on-chip for power management in a multi-die structure.

To meet the increasing market demand for higher performance in semiconductor devices, such as memory capacity or processing speed, research into three-dimensional integrated circuits (3D ICs) (or stacked memory devices) formed by stacking semiconductor dies is actively underway.

For example, research is being conducted to implement semiconductor devices formed by stacking a plurality of dies to include various functions in a smaller area.

In a 3D IC structure formed by stacking a plurality of dies, different levels of power (or voltage) may be supplied to the respective dies.

Due to the limitation of a configuration according to the related art to control power of a semiconductor device, it may be difficult to stably control power for the operation of each of the plurality of dies.

In addition, when different levels of power are supplied to the respective dies, issues may arise in an operation requiring an interaction between the plurality of dies.

### SUMMARY

Example embodiments provide a system-on-chip for stably controlling power for the operation of each of a plurality of dies.

According to some example embodiments, a system-on-chip (SoC) includes a first die and a second die adjacent to a surface of the first die, the second die connected to the first die. The first die may include a first reset circuit configured to output a first reset signal to operate the first die based on a first voltage received from a power supply, and the second die may include a second reset circuit configured to output a second reset signal to operate the second die based on a second voltage received from the power supply.

According to some example embodiments, a system-on-chip (SoC) includes a first die, a second die adjacent to a surface of the first die, the second die connected to the first die through a plurality of pads on the surface of the first die, and an external reset circuit configured to output a first reset signal based on a first voltage received from a power supply, and output a second reset signal based on a second voltage received from the power supply. The first die may be configured to operate with the first voltage in response to the first reset signal, and the second die may be configured to operate with the second voltage in response to the second reset signal.

According to some example embodiments, a system-on-chip (SoC) includes a first die and a second die adjacent to a surface of the first die, the second die connected to the first die through a plurality of pads disposed on the surface of the first die. The first die may include a first reset circuit configured output a first reset signal to operate the first die based on a supply voltage received from a power supply, and the second die may include a second reset circuit configured to output a second reset signal, different from the first reset signal, to operate the second die based on the supply voltage.

### BRIEF DESCRIPTION OF DRAWINGS

FIG. 1 is a diagram illustrating a system-on-chip having a multi-die structure according to some example embodiments.

FIG. 2 is a diagram illustrating a system-on-chip, in which a plurality of dies each include a reset circuit, according to some example embodiments.

FIG. 3 is a diagram illustrating a system-on-chip, in which a plurality of dies each further include a power management circuit, according to some example embodiments.

FIG. 4 is a diagram illustrating a system-on-chip, in which a plurality of dies each include a processor, according to some example embodiments.

FIG. 5A is a diagram illustrating a system-on-chip, in which a plurality of dies each further include a logic circuit, according to some example embodiments.

FIG. 5B is a diagram illustrating a system-on-chip, in which logic circuits each include an AND gate, according to some example embodiments.

FIG. 5C is a diagram illustrating a configuration in which a first logic circuit of FIG. 5B outputs a first output reset signal based on a first reset signal and a first external reset signal.

FIG. 5D is a diagram illustrating a system-on-chip, in which logic circuits each includes a plurality of AND gates, according to some example embodiments.

FIG. 6 is a diagram illustrating a system-on-chip including an external reset circuit according to some example embodiments.

FIG. 7 is a diagram illustrating a system-on-chip, including an external reset circuit according to some example embodiments, in which a plurality of dies each include a power management circuit.

FIG. 8 is a diagram illustrating a system-on-chip, in which a reset circuit included in each die outputs different reset signals based on a supply voltage, according to some example embodiments.

FIG. 9 is a diagram illustrating a system-on-chip, in which a plurality of dies each further includes a power management circuit, according to some example embodiments.

FIG. 10 is a diagram illustrating a system-on-chip, in which each of the plurality of dies includes a processor, according to some example embodiments.

FIG. 11 is a diagram illustrating a system-on-chip, in which each of the plurality of dies further includes a logic circuit, according to some example embodiments.

FIG. 12 is a diagram illustrating a system-on-chip including an external reset circuit outputting an external reset signal based on a supply voltage according to some example embodiments.

FIG. 13 is a diagram illustrating a system-on-chip, including an external reset circuit according to some example embodiments, in which each die includes a power management circuit.

FIG. 14A is a diagram illustrating a configuration in which a first die and a second die according to some example embodiments operate in response to a first reset signal generated from the first die.

FIG. 14B is a diagram illustrating a configuration in which a first die and a second die according to some example embodiments operate in response to a second reset signal generated from the second die.

FIG. 15A is a diagram illustrating a configuration in which a first die and a second die according to some example embodiments operate in response to a first output reset signal output from a first logic circuit.

FIG. 15B is a diagram illustrating a configuration in which a first die and a second die according to some example embodiments operate in response to a second output reset signal output from a second logic circuit.

FIG. 16 is a diagram illustrating a system-on-chip in which a first die according to some example embodiments further includes a plurality of level shifters.

### DETAILED DESCRIPTION

Hereinafter, some example embodiments will be described with reference to the accompanying drawings.

The terms, such as “first,” “second,” or the like, may represent various elements regardless of order and/or importance. Such terms may only be used to distinguish one element from another element, and do not limit the order and/or importance of the elements.

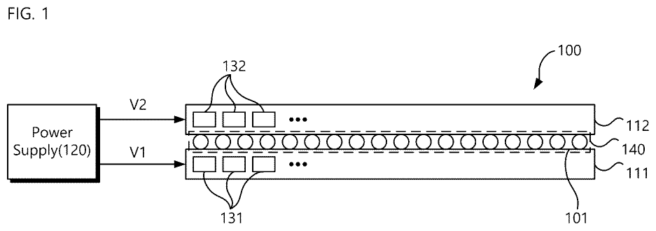

FIG. 1 is a diagram illustrating a system-on-chip having a multi-die structure according to some example embodiments.

Referring to FIG. 1, a system-on-chip (SoC) 100 according to some example embodiments may include a first die 111 and a second die 112.

For example, the system-on-chip 100 may include a first die 111 including a plurality of first intellectual property (IP) blocks 131. In some example embodiments, the system-on-chip 100 may include a second die 112 including a plurality of second IP blocks 132.

For example, the plurality of first IP blocks 131 and the plurality of second IP blocks 132 may each be understood as an electronic circuit performing a designated function or executing a designated application. In some example embodiments, any devices, electronic devices, modules, units, and/or portions thereof according to any of the example embodiments, and/or any portions thereof, including, without limitation, the plurality of first IP blocks 131 and the plurality of second IP blocks 132 may include, may be included in, and/or may be implemented by one or more instances of processing circuitry such as hardware including logic circuits; a hardware/software combination such as a processor executing software; or a combination thereof.

For example, a portion of the plurality of first IP blocks 131 and the plurality of second IP blocks 132 may be referred to as a processor or a power management unit (PMU), but example embodiments are not limited thereto.

For example, at least a portion of the plurality of first IP blocks 131 and the plurality of second IP blocks 132 may execute applications supported by the system-on-chip 100. Accordingly, in some example embodiments, at least a portion of the plurality of first IP blocks 131 and the plurality of second IP blocks 132 may also be referred to as an application processor (AP), or the like.

According to some example embodiments, the second die 112 may be disposed adjacent to a first surface 101 of the first die 111. For example, the second die 112 may be disposed adjacent to the first surface 101 of the first die 111 to be connected to the first die 111.

For example, the second die 112 may be connected to the first die 111 through a plurality of pads 140 disposed on the first surface 101 of the first die 111.

For example, the second die 112 may be stacked on the first surface 101 of the first die 111.

Accordingly, in some example embodiments the system-on-chip 100 including a plurality of dies 111 and 112 implemented to be stacked may be understood to have a three-dimensional integrated circuit (3D IC) structure.

The plurality of dies 111 and 112 according to some example embodiments may operate using different voltages (or powers) V1 and V2 transmitted, transferred, or sent from a power supply 120, respectively.

For example, the first die 111 may operate using a first voltage V1 transmitted, transferred, or sent from the power supply 120. For example, the first die 111 may operate at least a portion of the plurality of first IP blocks 131 using the first voltage V1 transmitted, transferred, or sent from the power supply 120.

The second die 112 may operate using a second voltage V2 transmitted, transferred, or sent from the power supply 120. For example, the second die 112 may operate at least a portion of the plurality of second IP blocks 132 using the second voltage V2 transmitted, transferred, or sent from the power supply 120.

For example, the first voltage V1 and the second voltage V2 may have different values, but example embodiments are not limited thereto.

For example, the stacked dies 111 and 112 may operate using different voltages V1 and V2 supplied from the power supply 120, respectively.

Thus, in some example embodiments, the system-on-chip 100 may independently control power for the operation of each of the stacked dies 111 and 112 using different voltages.

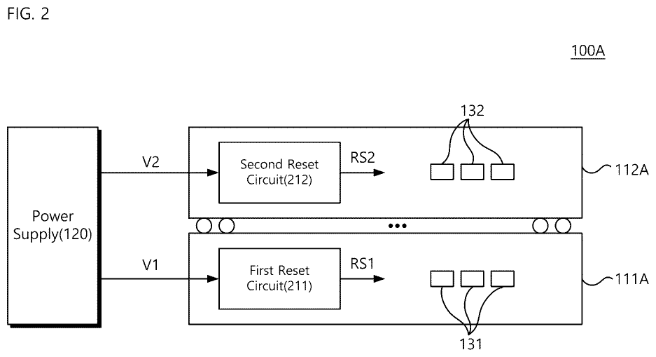

FIG. 2 is a diagram illustrating a system-on-chip, in which a plurality of dies each include a reset circuit, according to some example embodiments.

Referring to FIG. 2, a system-on-chip SoC 100A may include a plurality of dies 111A and 112A, respectively including reset circuits 211 and 212.

The system-on-chip 100A illustrated in FIG. 2 may be understood as an example of the system-on-chip 100 illustrated in FIG. 1. Therefore, the same or substantially the same components are denoted by the same or substantially the same reference numerals, and redundant descriptions are omitted to avoid repetition.

Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

According to some example embodiments, the first die 111A may include a first reset circuit 211. For example, the first die 111A may include a first reset circuit 211 outputting a first reset signal RS1 in response to a first voltage V1 transmitted, transferred, or sent from a power supply 120.

According to some example embodiments, the first reset circuit 211 may output the first reset signal RS1 in response to the first voltage V1 being stabilized.

For example, the first reset circuit 211 may output the first reset signal RS1 in response to a change amount (e.g., a change in an amount) of the first voltage V1 being less than a threshold value for a unit time.

The second die 112A may include a second reset circuit 212. For example, the second die 112A may include a second reset circuit 212 outputting a second reset signal RS2 in response to a second voltage V2 transmitted, transferred, or sent from the power supply 120.

The second reset circuit 212 according to some example embodiments may output the second reset signal RS2 in response to the second voltage V2 being stabilized.

For example, the second reset circuit 212 may output the second reset signal RS2 in response to a change amount of the second voltage V2 being less than a threshold value for a unit time.

The multiple dies 111A and 112A according to some example embodiments may operate in response to the reset signals RS1 and RS2, respectively.

For example, the first die 111A may operate using the first voltage V1 in response to the first reset signal RS1.

For example, the first die 111A may operate at least a portion of the plurality of first IP blocks 131 using the first voltage V1 in response to the first reset circuit 211 outputting a first reset signal RS1 having a high level.

In some example embodiments, the second die 112A may operate using the second voltage V2 in response to the second reset signal RS2.

For example, the second die 112A may operate at least a portion of the plurality of second IP blocks 132 using the second voltage V2 in response to the second reset circuit 212 outputting a second reset signal RS2 having a high level.

Referring to the above-described configurations, the system-on-chip 100A according to some example embodiments may include reset circuits 211 and 212, respectively provided in the plurality of dies 111A and 112A.

In some example embodiments, the system-on-chip 100A may output different reset signals RS1 and RS2 for the plurality of dies 111A and 112A using reset circuits 211 and 212.

As a result, the system-on-chip 100A according to some example embodiments may independently and stably control a power-on reset operation for each of the plurality of dies 111A and 112A.

Furthermore, in some example embodiments, the system-on-chip 100A may stably control power for the operation of each of the plurality of dies 111A and 112A through the above-described configurations.

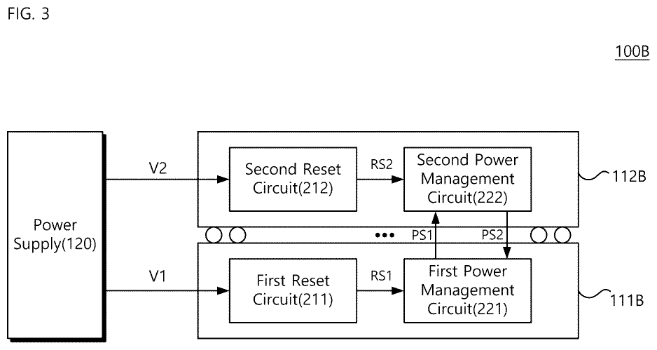

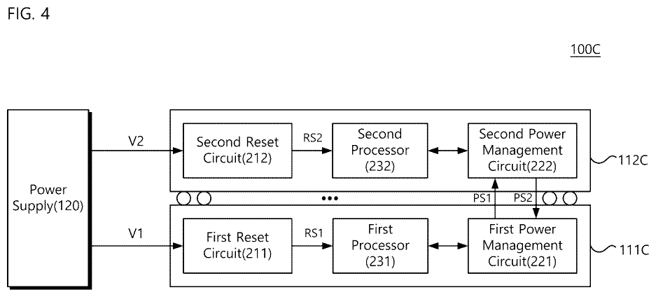

FIG. 3 is a diagram illustrating a system-on-chip, in which a plurality of dies each further include a power management circuit, according to some example embodiments. FIG. 4 is a diagram illustrating a system-on-chip, in which a plurality of dies each include a processor, according to some example embodiments.

Referring to FIG. 3, a system-on-chip 100B according to some example embodiments may include a first die 111B and a second die 112B. The first die 111B and the second die 112B may include reset circuits 211 and 212 and power management circuits 221 and 222, respectively.

The system-on-chip 100B illustrated in FIG. 3 may be understood as an example embodiments that further includes power management circuits 221 and 222, in addition to the configuration of the system-on-chip 100A illustrated in FIG. 2. Therefore, the same or substantially the same components are denoted by the same or substantially the same reference numerals, and redundant descriptions are omitted to avoid repetition.

According to some example embodiments, the first die 111B may include a first power management circuit 221.

For example, the first power management circuit 221 may transmit, transfer, or send first power information PS1 to the second die 112B. In some example embodiments, the first power management circuit 221 may receive second power information PS2 from the second die 112B.

The second die 112B may include a second power management circuit 222.

For example, the second power management circuit 222 may transmit, transfer, or send the second power information PS2 to the first die 111B. In some example embodiments, the second power management circuit 222 may receive first power information PS1 from the first die 111B.

For example, the first power information PS1 may include information on whether the first die 111B is operating. In some example embodiments, for example, the first power information PS1 may include at least one of a magnitude of the first voltage V1 supplied to the first die 111B, an amount of power consumed by the first die 111B, and state information of the first die 111B.

However, the information included in the first power information PS1 is not limited thereto, and, in some example embodiments, the first power information PS1 may be understood to include various information on an operating state and a power state of the first die 111B.

For example, the second power information PS2 may include information on whether the second die 112B is operating. In some example embodiments, for example, the second power information PS2 may include at least one of a magnitude of the second voltage V2 supplied to the second die 112B, an amount of power consumed by the second die 112B, and state information of the second die 112B.

However, the information included in the second power information PS2 is not limited thereto, and, in some example embodiments, the second power information PS2 may be understood to include various information on an operating state and a power state of the second die 112B.

For example, the first power management circuit 221 and the second power management circuit 222 may exchange the first power information PS1 and the second power information PS2 through a through-silicon via (TSV). The TSV may be formed to penetrate through at least a portion of each of the first die 111B and the second die 112B.

For example, the first power management circuit 221 may receive the second power information PS2 from the second power management circuit 222. In some example embodiments, the second power management circuit 222 may receive the first power information PS1 from the first power management circuit 221.

Referring to FIG. 4, a system-on-chip 100C according to some example embodiments may include a first die 111C and a second die 112C. The first die 111C and the second die 112C may include reset circuits 211 and 212, power management circuits 221 and 222, and processors 231 and 232, respectively.

The system-on-chip 100C illustrated in FIG. 4 may be understood as an example that includes a first processor 231 and a second processor 232, in addition to the configuration of the system-on-chip 100B illustrated in FIG. 3.

Therefore, the same or substantially the same components are denoted by the same or substantially the same reference numerals, and redundant descriptions are omitted to avoid repetition.

According to some example embodiments, the first die 111C may include a first processor 231 controlling an operation of the first die 111C. For example, the first processor 231 may be configured to control the operation of the first die 111C.

The first processor 231 may be configured to execute software (or a program) to control at least a portion of one or more other components of the first die 111C (for example, the first IP blocks 131 of FIG. 1) and perform various data processing or operations. In some example embodiments, the first processor 231 may include a central processing unit (CPU), a microprocessor, or the like, and may control the overall operation of the first die 111C. Therefore, an operation performed by the first die 111C may be understood to be performed under the control of the first processor 231.

The second die 112C may include a second processor 232 controlling an operation of the second die 112C. For example, the second processor 232 may be configured to control the operation of the second die 112C.

The second processor 232 may be configured to execute software (or a program) to control at least portion of one or more other components of the second die 112C (for example, the second IP blocks 132 of FIG. 1) and perform various data processing or operations. In some example embodiments, the second processor 232 may include a central processing unit (CPU), a microprocessor, or the like, and may control the overall operation of the second die 112C. Therefore, the operation performed by the second die 112C may be understood to be performed under the control of the second processor 232.

Referring to FIGS. 3 and 4, the first processor 231 may determine whether the second die 112C is operating, based on the second power information PS2.

The first processor 231 may operate based on whether the second die 112C is operating while the first reset signal RS1 is input.

For example, the first processor 231 may operate based on whether the second die 112C is operating when an interaction (for example, data exchange) between the first die 111C and the second die 112C is required. In some example embodiments, the first processor 231 may operate based on whether the second die 112C is operating when an interaction between the first die 111C and the second die 112C is desired.

For example, when receiving an execution request for an application that requires data exchange between the first die 111C and the second die 112C, the first processor 231 may determine whether the second die 112C is operating, based on the second power information PS2.

When the second die 112C is operating, the first processor 231 may control the operation of the first die 111C based on a data signal received from the second die 112C to execute an application that has received the execution request.

For example, when the second die 112C is operating, the first processor 231 may operate at least a portion of the plurality of first IP blocks (for example, 131 of FIG. 1) to execute an application that has received the execution request.

According to some example embodiments, when the second die 112C is not operating, the first processor 231 may output a first operation request to operate the second die 112C.

For example, when the second die 112C is not operating, the first processor 231 may output the first operation request to at least one of the power supply 120 and the second reset circuit 212 to operate the second die 112C.

The second processor 232 according to some example embodiments may determine whether the first die 111C is operating, based on the first power information PS1.

In some example embodiments, the second processor 232 may operate based on whether the first die 111C is operating while, or concurrently with, the second reset signal RS2 is input.

For example, the second processor 232 may operate based on whether the first die 111C is operating when an interaction (for example, data exchange) between the first die 111C and the second die 112C is required.

For example, when receiving an execution request for an application that requires data exchange between the first die 111C and the second die 112C, the second processor 232 may determine whether the first die 111C is operating, based on the first power information PS1.

In some example embodiments, when the first die 111C is operating, the second processor 232 may control the operation of the second die 112C based on the data signal, received from the first die 111C, to execute the application that has received the execution request.

For example, when the first die 111C is operating, the second processor 232 may operate at least a portion of the plurality of second IP blocks (for example, 132 of FIG. 1) to execute the application that has received the execution request.

According to some example embodiments, when the first die 111C is not operating, the second processor 232 may output a second operation request to operate the first die 111C.

For example, when the first die 111C is not operating, the second processor 232 may output the second operation request to at least a portion of the power supply 120 and the first reset circuit 211 to operate the first die 111C.

Referring to the above-described configurations, in some example embodiments, each of the first processor 231 and the second processor 232 may determine whether another die is operating, based on the power information PS1 and PS2 received through the power management circuit 221 and 222. For example, the first processor 231 may determine whether the second die 112C is operating based on the power information PS2 received through the power management circuit 221. Similarly, in some example embodiments, the second processor 232 may determine whether the first die 111C is operating based on the power information PS1 received through the power management circuit 222.

Furthermore, in some example embodiments, each of the first processor 231 and the second processor 232 may perform an operation, which may require an interaction between the first die 111C and the second die 112C, in response to another die being operating.

Thus, according to some example embodiments, the system-on-chip 100C may reduce the time it takes to turn on the plurality of dies 111C and 112C when an interaction between the plurality of dies 111C and 112C is required.

In some example embodiments, the system-on-chip 100C may stably control the power for the operation of each of the plurality of dies 111C and 112C when an interaction between the plurality of dies 111C and 112C is required.

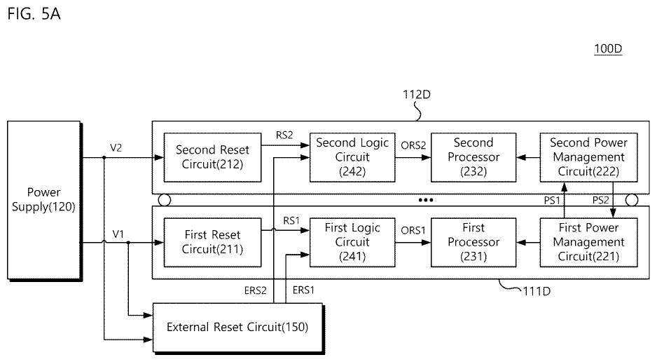

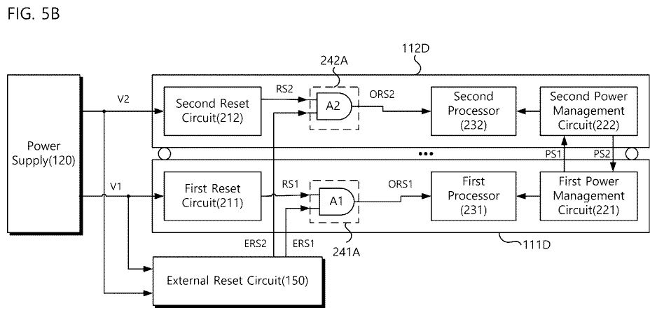

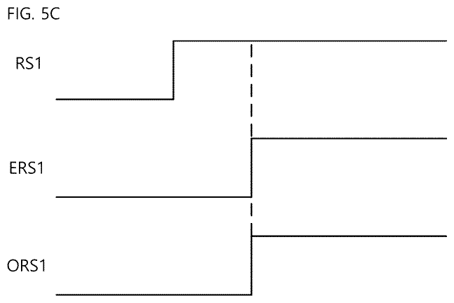

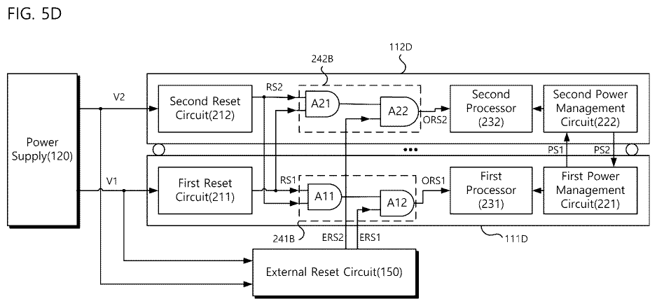

FIG. 5A is a diagram illustrating a system-on-chip, in which a plurality of dies each further include a logic circuit, according to some example embodiments. FIG. 5B is a diagram illustrating a system-on-chip, in which logic circuits each include an AND gate, according some example embodiments. FIG. 5C is a diagram illustrating a configuration in which a first logic circuit of FIG. 5B outputs a first output reset signal based on a first reset signal and a first external reset signal according to some example embodiments. FIG. 5D is a diagram illustrating a system-on-chip, in which logic circuits each includes a plurality of AND gates, according to some example embodiments.

Referring to FIGS. 5A to 5D, a system-on-chip 100D according to some example embodiments may include an external reset circuit 150, a first die 111D, and a second die 112D.

The system-on-chip 100D illustrated in FIG. 5 may be understood as an example that includes an external reset circuit 150 and logic circuits 241 and 242, in addition to the configuration of the system-on-chip 100C illustrated in FIG. 4.

Therefore, the same or substantially the same components are denoted by the same or substantially the same reference numerals, and redundant descriptions are omitted to avoid repetition.

According to some example embodiments, the system-on-chip 100D may include an external reset circuit 150 outputting external reset signals ERS1 and ERS2 based on voltages V1 and V2 transmitted, transferred, or sent from the power supply 120.

For example, the external reset circuit 150 may output a first external reset signal ERS1 based on the first voltage V1 transmitted, transferred, or sent from the power supply 120. The first external reset signal ERS1 may be understood as a signal for resetting the power of the first die 111D to operate the first die 111D.

In some example embodiments, the external reset circuit 150 may output a second external reset signal ERS2 based on the second voltage V2 transmitted, transferred, or sent from the power supply 120. The second external reset signal ERS2 may be understood as a signal for resetting the power of the second die 112D to operate the second die 112D.

The first die 111D may include a first logic circuit 241 outputting a first output reset signal ORS1 based on at least one of the first reset signal RS1 and the first external reset signal ERS1.

In some example embodiments, the second die 112D may include a second logic circuit 242 outputting a second output reset signal ORS2 based on at least one of the second reset signal RS2 and the second external reset signal ERS2.

For example, the first logic circuit 241 may output the first output reset signal ORS1 through a logical operation between the first reset signal RS1 and the first external reset signal ERS1. The second logic circuit 242 may output the second output reset signal ORS2 through a logical operation between the second reset signal RS2 and the second external reset signal ERS2.

Referring to FIG. 5B, a first logic circuit 241A according to some example embodiments may include a first AND gate A1. The first AND gate A1 may perform a logical AND operation between a first reset signal RS1 and a first external reset signal ERS1.

The first logic circuit 241A may output the first output reset signal ORS1 as a result of the logical AND operation between the first reset signal RS1 and the first external reset signal ERS1.

Referring to FIGS. 5A and 5C, the first logic circuit 241A may output a first output reset signal ORS1 having a high level (e.g., a logic level “1”) when both the input first reset signal RS1 and the input first external reset signal ERS1 are high (e.g., logic level “1”).

The second logic circuit 242A may include a second AND gate A2. The second AND gate A2 may perform a logical AND operation between a second reset signal RS2 and a second external reset signal ERS2.

The second logic circuit 242A may output the second output reset signal ORS2 as a result of the logical AND operation between the second reset signal RS2 and the second external reset signal ERS2.

For example, the second logic circuit 242A may output a second output reset signal ORS2 having a high level when both the input second reset signal RS2 and the input second external reset signal ERS2 are high.

Referring to FIG. 5D, a first logic circuit 241B according to some example embodiments may include a plurality of AND gates A11 and A12, and a second logic circuit 242B may include a plurality of AND gates A21 and A22.

For example, the first logic circuit 241B may include a 1-1-th AND gate A11 and a 1-2-th AND gate A12.

The first logic circuit 241B may include a 1-1-th AND gate A11 performing a logical AND operation between the first reset signal RS1 and the second reset signal RS2.

In some example embodiments, the first logic circuit 241B may include a 1-2-th AND gate A12 performing a logical AND operation between a signal output from the 1-1-th AND gate A11 and a first external reset signal ERS1 output from the external reset circuit 150.

The first logic circuit 241B may output the first output reset signal ORS1 as a result of the logical AND operation through the 1-1-th AND gate A11 and the 1-2-th AND gate A12.

For example, the first logic circuit 241B may output a first output reset signal ORS1 having a high level in response to the first reset signal RS1, the second reset signal RS2, and the first external reset signal ERS1 being all high.

In some example embodiments, the second logic circuit 242B may include a 2-1-th AND gate A21 and a 2-2-th AND gate A22.

The second logic circuit 242B may include a 2-1-th AND gate A21 performing a logical AND operation between the first reset signal RS1 and the second reset signal RS2.

In some example embodiments, the second logic circuit 242B may include a 2-2 AND gate A22 performing a logical AND operation between a signal output from the 2-1-th AND gate A21 and the second external reset signal ERS2 output from the external reset circuit 150.

The second logic circuit 242B may output the second output reset signal ORS2 as a result of the logical AND operation through the 2-1-th AND gate A21 and the 2-2-th AND gate A22.

For example, the second logic circuit 242B may output a second output reset signal ORS2 having a high level in response to the first reset signal RS1, the second reset signal RS2, and the second external reset signal ERS2 being all high.

For example, the first external reset signal ERS1 and the second external reset signal ERS2 may be referred to as the same.

According to some example embodiments, referring to FIG. 5A, the logic circuits 241 and 242 may output the output reset signals ORS1 and ORS2 in response to one of the reset signals RS1 and RS2 or the external reset signals ERS1 and ERS2 based on a predetermined, or alternatively desired priority.

For example, the first logic circuit 241 may output the first output reset signal ORS1 in response to the first reset signal RS1.

The first logic circuit 241 may output a first output reset signal ORS1 having a high level when the first reset signal RS1 is high (e.g., logic level “1”) and the first external reset signal ERS1 is low (e.g., logic level “0”).

For example, the first logic circuit 241 may output the reset output signal ORS1, prioritizing the reset signal RS1 over the external reset signal ERS1.

In some example embodiments, the second logic circuit 242 may output the second output reset signal ORS2 in response to the second external reset signal ERS2.

For example, the second logic circuit 242 may output a second output reset signal ORS2 having a high level when the second reset signal RS2 is low and the second external reset signal ERS2 is high.

For example, the second logic circuit 242 may output the second output reset signal ORS2, prioritizing the second external reset signal ERS2 over the second reset signal RS2.

In some example embodiments, the first processor 231 may operate the first die 111D in response to the first output reset signal ORS1.

For example, the first processor 231 may reset the power for the operation of the first die 111D in response to the first output reset signal ORS1. Thus, the first processor 231 may operate the first die 111D.

In some example embodiments, the second processor 232 may operate the second die 112D in response to the second output reset signal ORS2.

For example, the second processor 232 may reset the power for the operation of the second die 112D in response to the second output reset signal ORS2. Thus, the second processor 232 may operate the second die 112D.

Referring to the above-described configurations, each of the plurality of dies 111D and 112D according to some example embodiments may operate based on at least a portion of signals, output from the reset circuits 211 and 212 included therein, and a signal output from the external reset circuit 150.

Accordingly, in some example embodiments, the system-on-chip 100D may stably control a power-on reset (POR) operation of each of the plurality of dies 111D and 112D.

Furthermore, in some example embodiments, the system-on-chip 100D may stably control the power for the operation of each of the plurality of dies 111D and 112D through the above-described configurations.

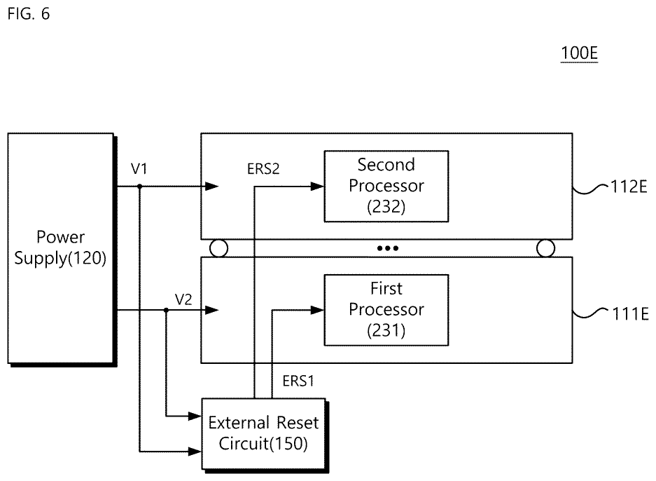

FIG. 6 is a diagram illustrating a system-on-chip including an external reset circuit according to some example embodiments.

Referring to FIG. 6, a system-on-chip 100E may include a plurality of dies 111E and 112E and an external reset circuit 150.

The system-on-chip 100E illustrated in FIG. 6 may be understood as an example of the system-on-chip 100 illustrated in FIG. 1. Therefore, the same or substantially the same components are denoted by the same or substantially the same reference numerals, and redundant descriptions are omitted to avoid repetition.

According to some example embodiments, the system-on-chip 100E may include an external reset circuit 150 connected between the power supply 120 and the plurality of dies 111E and 112E.

For example, the external reset circuit 150 may output a first external reset signal ERS1 in response to a first voltage V1 transmitted, transferred, or sent from the power supply 120.

According to some example embodiments, the external reset circuit 150 may output the first external reset signal ERS1 in response to the first voltage V1 being stabilized.

For example, the external reset circuit 150 may output the first external reset signal ERS1 in response to a change amount of the first voltage V1 being less than a threshold value for a unit time.

In some example embodiments, the external reset circuit 150 may output a second external reset signal ERS2 in response to a second voltage V2 transmitted, transferred, or sent from the power supply 120.

According to some example embodiments, the external reset circuit 150 may output the second external reset signal ERS2 in response to the second voltage V2 being stabilized.

For example, the external reset circuit 150 may output the second external reset signal ERS2 in response to a change amount of the second voltage V2 being less than a threshold value for a unit time.

In addition, the plurality of dies 111E and 112E according to some example embodiments may operate in response to the external reset signals ERS1 and ERS2, respectively.

According to some example embodiments, the first processor 231 may operate the first die 111E in response to the first external reset signal ERS1. For example, the first processor 231 may operate the first die 111E in response to a first external reset signal ERS1 having a high level.

For example, the first processor 231 may reset power for the operation of the first die 111E in response to the first external reset signal ERS1. Thus, the first processor 231 may operate the first die 111E.

For example, the first processor 231 may operate at least a portion of a plurality of first IP blocks (for example, 131 of FIG. 1), included in the first die 111E, using the first voltage V1 in response to the first external reset signal ERS1.

According to some example embodiments, the second processor 232 may operate the second die 112E in response to the second external reset signal ERS2. For example, the second processor 232 may operate the second die 112E in response to a second external reset signal ERS2 having a high level.

For example, the second processor 232 may reset power for the operation of the second die 112E in response to the second external reset signal ERS2. Thus, the second processor 232 may operate the second die 112E.

For example, the second processor 232 may operate at least one of a plurality of second IP blocks (for example, 132 of FIG. 1), included in the second die 112E, using the second voltage V2 in response to the second external reset signal ERS2.

Referring to the above-described configurations, the external reset circuit 150 according to some example embodiments may output different external reset signals ERS1 and ERS2 for the plurality of dies 111E and 112E using different voltages (or power) V1 and V2.

As a result, the system-on-chip 100E according to some example embodiments may independently and stably control a power-on reset operation for each of the plurality of dies 111E and 112E.

Furthermore, in some example embodiments, the system-on-chip 100E may stably control power for the operation of each of the plurality of dies 111E and 112E through the above-described configurations.

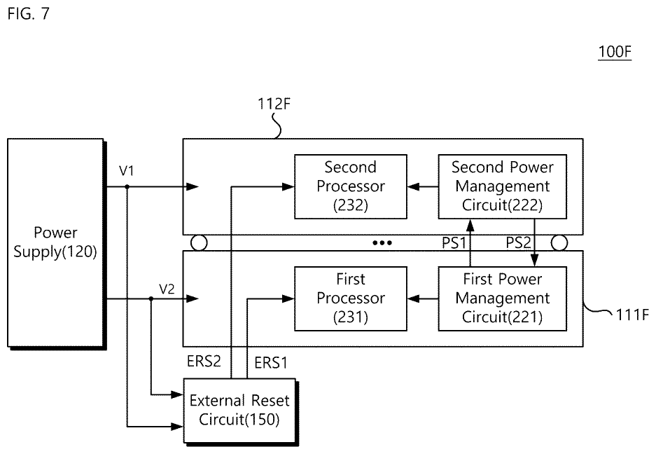

FIG. 7 is a diagram illustrating a system-on-chip, including an external reset circuit according to some example embodiments, in which a plurality of dies each include a power management circuit.

Referring to FIG. 7, a system-on-chip 100F according to some example embodiments may include a first die 111F and a second die 112F. The first die 111F and the second die 112F may include processors 231 and 232 and power management circuits 221 and 222, respectively.

The system-on-chip 100F illustrated in FIG. 7 may be understood as an example that further includes power management circuits 221 and 222, in addition to the configuration of the system-on-chip 100E illustrated in FIG. 6. Therefore, the same or substantially the same components are denoted by the same or substantially the same reference numerals, and redundant descriptions are omitted to avoid repetition.

According to some example embodiments, the first die 111F may further include a first power management circuit 221.

For example, the first power management circuit 221 may transmit, transfer, or send first power information PS1 to the second die 112F. In some example embodiments, the first power management circuit 221 may receive second power information PS2 from the second die 112F.

In some example embodiments, the second die 112F may further include a second power management circuit 222.

For example, the second power management circuit 222 may transmit, transfer, or send second power information PS2 to the first die 111F. In some example embodiments, the second power management circuit 222 may receive first power information PS1 from the first die 111F.

For example, the first power information PS1 may include information on whether the first die 111F is operating. For example, the second power information PS2 may include information on whether the second die 112F is operating.

For example, the first power management circuit 221 and the second power management circuit 222 may exchange first power information PS1 and second power information PS2 through a through-silicon via (TSV).

According to some example embodiments, the first processor 231 may determine whether the second die 112F is operating, based on the second power information PS2.

Furthermore, the first processor 231 may operate based on whether the second die 112F is operating while the first external reset signal ERS1 is input.

For example, the first processor 231 may operate based on whether the second die 112F is operating when an interaction (for example, data exchange) between the first die 111F and the second die 112F is required.

For example, when receiving an execution request for an application that requires data exchange between the first die 111F and the second die 112F, the first processor 231 may determine whether the second die 112F is operating, based on the second power information PS2.

Furthermore, when the second die 112F is operating, the first processor 231 may control the operation of the first die 111F based on a data signal, received from the second die 112F, to execute an application that have received an execution request.

The first processor 231 may operate the first die 111F using the first voltage V1 transmitted, transferred, or sent from the power supply 120.

In some example embodiments, the second processor 232 may determine whether the first die 111F is operating based on the first power information PS1.

The second processor 232 may operate based on whether the first die 111F is operating while the second reset signal RS2 is output.

For example, the second processor 232 may operate based on whether the first die 111F is operating when an interaction (for example, data exchange) between the first die 111F and the second die 112F is required.

For example, when receiving an execution request for an application that requires data exchange between the first die 111F and the second die 112F, the second processor 232 may determine whether the first die 111F is operating based on the first power information PS1.

When the first die 111F is operating, the second processor 232 may control the operation of the second die 112F based on a data signal, received from the first die 111F, to execute an application that has received an execution request.

The second processor 232 may operate the second die 112F using the second voltage V2 transmitted, transferred, or sent from the power supply 120.

Referring to the above-described configurations according to some example embodiments, the first processor 231 and the second processor 232 may determine whether another die is operating, based on the power information PS1 and PS2 received through the power management circuits 221 and 222, respectively.

Furthermore, in some example embodiments, each of the first processor 231 and the second processor 232 may perform an operation of requesting the first die 111F and the second die 112F to operate together in response to the other die being operating.

Accordingly, in some example embodiments, the system-on-chip 100F may reduce the time it takes to operate the plurality of dies 111F and 112F when an interaction between the plurality of dies 111F and 112F is required.

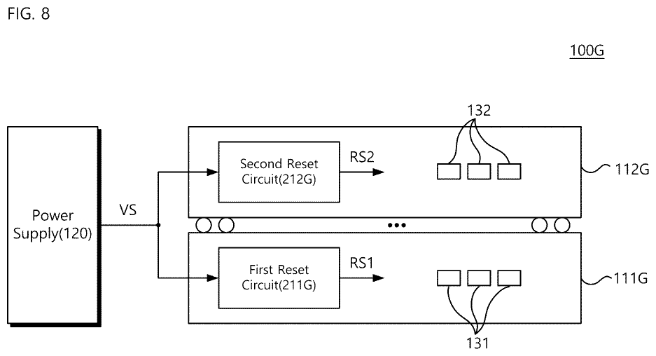

FIG. 8 is a diagram illustrating a system-on-chip, in which a reset circuit included in each die outputs different reset signals based on a supply voltage, according to some example embodiments.

Referring to FIG. 8, a system-on-chip 100G may include a plurality of dies 111G and 112G, respectively including reset circuits 211G and 212G.

The system-on-chip 100G and the reset circuits 211G and 212G illustrated in FIG. 8 may be understood as examples of the system-on-chip 100A and the reset circuits 211 and 212 illustrated in FIG. 2. Therefore, the same or substantially the same components are denoted by the same or substantially the same reference numerals, and redundant descriptions are omitted to avoid repetition.

According to some example embodiments, the first die 111G may include a first reset circuit 211G. For example, the first die 111G may include a first reset circuit 211G outputting a first reset signal RS1 in response to a supply voltage VS transmitted, transferred, or sent from a power supply 120.

According to some example embodiments, the first reset circuit 211G may output the first reset signal RS1 in response to the supply voltage VS being stabilized.

For example, the first reset circuit 211G may output the first reset signal RS1 in response to a change amount of the supply voltage VS being less than a threshold value for a unit time.

The second die 112G may include a second reset circuit 212G. For example, the second die 112G may include a second reset circuit 212G outputting a second reset signal RS2 in response to the supply voltage VS transmitted, transferred, or sent from the power supply 120.

The second reset circuit 212G according to some example embodiments may output the second reset signal RS2 in response to the supply voltage VS being stabilized.

For example, the second reset circuit 212G may output the second reset signal RS2 in response to a change amount of the supply voltage VS being less than a threshold value for a unit time.

In some example embodiments, the plurality of dies 111G and 112G may operate in response to the reset signals RS1 and RS2, respectively.

For example, the first die 111G may operate using the supply voltage VS in response to the first reset signal RS1.

For example, the first die 111G may operate at least a portion of a plurality of first IP blocks 131 using the supply voltage VS in response to the first reset circuit 211G outputting a first reset signal RS1 having a high level.

The second die 112G may operate using the supply voltage VS in response to the second reset signal RS2.

For example, the second die 112G may operate at least a portion of a plurality of second IP blocks 132 using the supply voltage VS in response to the second reset circuit 212G outputting a second reset signal RS2 having a high level.

Referring to the above-described configurations, the system-on-chip 100G according to some example embodiments may include reset circuits 211G and 212G, respectively provided in the plurality of dies 111G and 112G.

The reset circuits 211G and 212G may output the different reset signals RS1 and RS2 from the supply voltage VS transmitted, transferred, or sent from the power supply 120.

The plurality of dies 111G and 112G may operate in response to the different reset signals RS1 and RS2, respectively.

As a result, the system-on-chip 100G according to some example embodiments may independently and stably control a power-on reset operation for each of the plurality of dies 111G and 112G.

Furthermore, in some example embodiments, the system-on-chip 100G may stably control power for the operation of each of the plurality of dies 111G and 112G through the above-described configurations.

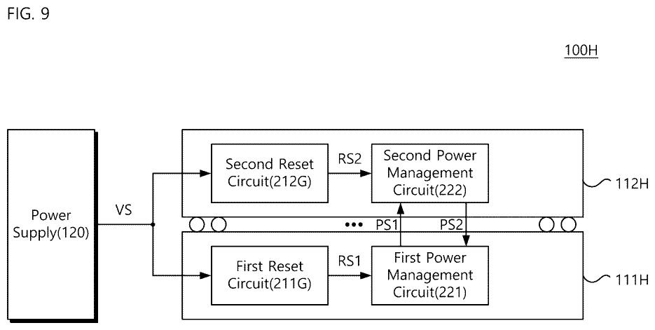

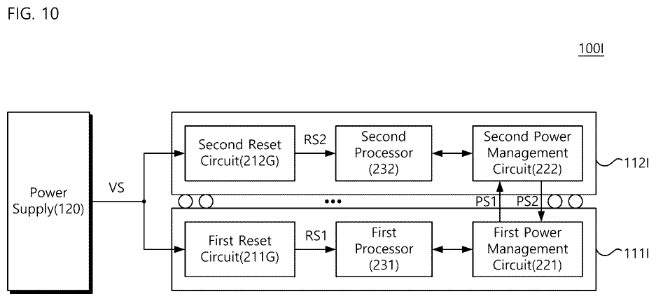

FIG. 9 is a diagram illustrating a system-on-chip, in which a plurality of dies each further includes a power management circuit, according to some example embodiments. FIG. 10 is a diagram illustrating a system-on-chip, in which each of the plurality of dies includes a processor, according to some example embodiments.

Referring to FIG. 9, a system-on-chip 100H according to some example embodiments may include a first die 111H and a second die 112H. The first die 111H and the second die 112H may include reset circuits 211G and 212G and power management circuits 221 and 222, respectively.

The system-on-chip 100H illustrated in FIG. 9 may be understood as a configuration in which the first and second dies 111H and 112H further include power management circuits 221 and 222, respectively, in addition to the configuration of the system-on-chip 100G illustrated in FIG. 8. Therefore, the same or substantially the same components are denoted by the same or substantially the same reference numerals, and redundant descriptions are omitted to avoid repetition.

According to some example embodiments, the first die 111H may further include a first power management circuit 221.

For example, the first power management circuit 221 may transmit, transfer, or send first power information PS1 to the second die 112H. In some example embodiments, the first power management circuit 221 may receive second power information PS2 from the second die 112H.

According to some example embodiments, the second die 112H may further include a second power management circuit 222.

For example, the second power management circuit 222 may transmit, transfer, or send second power information PS2 to the first die 111H. In some example embodiments, the second power management circuit 222 may receive first power information PS1 from the first die 111H.

For example, the first power information PS1 may include information on whether the first die 111H is operating. In some example embodiments, for example, the first power information PS1 may include at least a portion of a magnitude of the supply voltage VS supplied to the first die 111H, an amount of power consumed by the first die 111H, and state information of the first die 111H.

However, the information included in the first power information PS1 is not limited thereto, and, in some example embodiments the first power information PS1 may be understood as including various information on an operating state and a power state of the first die 111H.

For example, the second power information PS2 may include information on whether the second die 112H is operating. In some example embodiments, for example, the second power information PS2 may include at least a portion of a magnitude of the supply voltage VS supplied to the second die 112H, an amount of power consumed by the second die 112H, and state information of the second die 112H.

However, the information included in the second power information PS2 is not limited thereto, and, and in some example embodiments, the second power information PS2 may be understood as including various types of information on an operating state and a power state of the second die 112H.

Referring to FIG. 10, a system-on-chip 100I according to some example embodiments may include a first die 1111 and a second die 1121. The first die 1111 and the second die 1121 may include reset circuits 211G and 212G, power management circuits 221 and 222, and processors 231 and 232, respectively.

The system-on-chip 100I illustrated in FIG. 10 may be understood as an example that further includes a first processor 231 and a second processor 232, in addition to the configuration of the system-on-chip 100H illustrated in FIG. 9.

Therefore, the same or substantially the same components are denoted by the same or substantially the same reference numerals, and redundant descriptions are omitted to avoid repetition.

According to some example embodiments, the first die 111I may include a first processor 231 controlling an operation of the first die 111I.

The first processor 231 may be configured to execute software (or a program) to control at least a portion of one or more other components of the first die 111I (for example, the first IP blocks 131 of FIG. 8) and perform various data processing or operations. In some example embodiments, the first processor 231 may include a central processing unit (CPU), a microprocessor, or the like, and may control the overall operation of the first die 111I. Therefore, an operation performed by the first die 111I may be understood to be performed under the control of the first processor 231.

The second die 112I may include a second processor 232 controlling an operation of the second die 112I.

The second processor 232 may be configured to execute software (or a program) to control at least a portion of one or more other components of the second die 112I (for example, the first IP blocks 132 of FIG. 8) and perform various data processing or operations. In some example embodiments, the second processor 232 may include a central processing unit (CPU), a microprocessor, or the like, and may control the overall operation of the second die 112I. Therefore, an operation performed by the second die 112I may be understood to be performed under the control of the second processor 232.

Referring to FIGS. 9 and 10, the first processor 231 may determine whether the second die 112I is operating, based on the second power information PS2.

The first processor 231 may operate based on whether the second die 1121 is operating while the first reset signal RS1 is input.

For example, the first processor 231 may operate based on whether the second die 112I is operating when an interaction (for example, data exchange) between the first die 111I and the second die 1121 is required.

For example, when receiving an execution request for an application that requires data exchange between the first die 1111 and the second die 112I, the first processor 231 may determine whether the second die 112I is operating, based on the second power information PS2.

When the second die 112I is operating, the first processor 231 may control the operation of the first die 1111 based on a data signal, received from the second die 112I, to execute an application that has received an execution request.

For example, when the second die 1121 is operating, the first processor 231 may operate at least a portion of a plurality of first IP blocks (for example, 131 of FIG. 8) using the supply voltage VS to execute an application that has received an execution request.

In some example embodiments, the second processor 232 may determine whether the first die 111I is operating, based on the first power information PS1.

According to some example embodiments, the second processor 232 may operate based on whether the first die 1111 is operating while the second reset signal RS2 is input.

For example, the second processor 232 may operate based on whether the first die 111I is operating when an interaction (for example, data exchange) between the first die 111I and the second die 112I is required.

For example, when receiving an execution request for an application that requires data exchange between the first die 1111 and the second die 112I, the second processor 232 may determine whether the first die 1111 is operating, based on the first power information PS1.

According to some example embodiments, when the first die 1111 is operating, the second processor 232 may control the operation of the second die 112I based on a data signal, received from the first die 111I, to execute an application that has received an execution request.

For example, when the first die 1111 is operating, the second processor 232 may operate at least a portion of a plurality of second IP blocks (for example, 132 of FIG. 8) using the supply voltage VS to execute an application that has received an execution request.

Referring to the above-described configurations, in some example embodiments, the first processor 231 and the second processor 232 may determine whether the other die is operating, based on the power information PS1 and PS2 received through the power management circuit 221 and 222, respectively.

According to some example embodiments, each of the first processor 231 and the second processor 232 may perform an operation of requesting the first die 1111 and the second die 112I to operate together in response to the other die being operating.

As a result, in some example embodiments, the system-on-chip 100I may reduce the time it takes to reset power of the plurality of dies 1111 and 1121 when an interaction between the plurality of dies 1111, 112I is required.

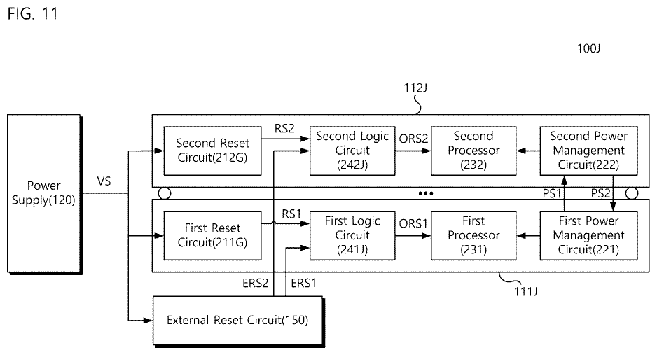

FIG. 11 is a diagram illustrating a system-on-chip, in which each of the plurality of dies further includes a logic circuit, according to some example embodiments.

Referring to FIG. 11, a system-on-chip 100J according to some example embodiments may include an external reset circuit 150, a first die 111J, and a second die 112J.

The system-on-chip 100J illustrated in FIG. 11 may be understood as an example that further includes logic circuits 241J and 242J, in addition to the configuration of the system-on-chip 100I illustrated in FIG. 10. Therefore, the same or substantially the same components are denoted by the same or substantially the same reference numerals, and redundant descriptions are omitted to avoid repetition.

The system-on-chip 100J may include an external reset circuit 150 outputting external reset signals ERS1 and ERS2 based on a supply voltage VS transmitted from a power supply 120.

For example, the external reset circuit 150 may output a first external reset signal ERS1 based on the supply voltage VS transmitted, transferred, or sent from the power supply 120. The first external reset signal ERS1 may be understood as a signal for resetting power of the first die 111J to operate the first die 111J.

In some example embodiments, the external reset circuit 150 may output a second external reset signal ERS2 based on the supply voltage VS transmitted, transferred, or sent from the power supply 120. The second external reset signal ERS2 may be understood as a signal for resetting power of the second die 112J to operate the second die 112J.

The system-on-chip 100J may include a first logic circuit 241J outputting a first output reset signal ORS1 based on at least a portion of a first reset signal RS1 and the first external reset signal ERS1.

In some example embodiments, the system-on-chip 100J may include a second logic circuit 242J outputting a second output reset signal ORS2 based on at least a portion of a second reset signal RS2 and the second external reset signal ERS2.

According to some example embodiments, each of the first and second logic circuits 241J and 242J may include an AND gate.

Thus, the first logic circuit 241A may output the first output reset signal ORS1 as a result of an AND operation between the first reset signal RS1 and the first external reset signal ERS1.

According to some example embodiments, the second logic circuit 242A may output the second output reset signal ORS2 as a result of the AND operation between the second reset signal RS2 and the second external reset signal ERS2.

In some example embodiments, each of the first and second logic circuits 241J and 242J may include a plurality of AND gates.

For example, the first logic circuit 241J may include an AND gate performing an AND operation between the first reset signal RS1 and the second reset signal RS2.

In some example embodiments, the first logic circuit 241J may include an AND gate performing an AND operation between the result of the AND operation between the first reset signal RS1 and the second reset signal RS2 and the first external reset signal ERS1.

The above-described configurations may allow the first logic circuit 241J to output the first output reset signal ORS1 as a result of an AND operation between the first reset signal RS1, the second reset signal RS2, and the first external reset signal ERS1.

In some example embodiments, the second logic circuit 242J may include an AND gate performing an AND operation between the first reset signal RS1 and the second reset signal RS2.

In some example embodiments, the second logic circuit 242J may include an AND gate performing an AND operation between the result of the AND operation between the first reset signal RS1 and the second reset signal RS2 and the second external reset signal ERS2.

The above-described configurations may allow the second logic circuit 242J to output the second output reset signal ORS2 as a result of an AND operation between the first reset signal RS1, the second reset signal RS2, and the second external reset signal ERS2.

In some example embodiments, the logic circuits 241J and 242J may output the output reset signals ORS1 and ORS2 in response to one of the reset signals RS1 and RS2 or external reset signals ERS1 and ERS2 based on a predetermined, or alternatively desired priority, respectively.

For example, the first logic circuit 241J may output a first output reset signal ORS1 having a high level when the first reset signal RS1 is high and the first external reset signal ERS1 is low.

For example, the first logic circuit 241J may output the first output reset signal ORS1, prioritizing the first reset signal RS1 over the first external reset signal ERS1.

For example, the second logic circuit 242J may output a second output reset signal ORS2 having a high level when the second reset signal RS2 is low and the second external reset signal ERS2 is high.

For example, the second logic circuit 242J may output the second output reset signal ORS2, prioritizing the second external reset signal ERS2 over the second reset signal RS2.

Furthermore, in some example embodiments, the first processor 231 may operate the first die 111J in response to the first output reset signal ORS1.

For example, the first processor 231 may reset power for an operation of the first die 111J in response to the first output reset signal ORS1. Thus, the first processor 231 may operate the first die 111J.

In some example embodiments, the second processor 232 may operate the second die 112J in response to the second output reset signal ORS2.

For example, the second processor 232 may reset power for an operation of the second die 112J in response to the second output reset signal ORS2. Thus, the second processor 232 may operate the second die 112J.

Referring to the above-described configurations, each of the plurality of dies 111J and 112J according to some example embodiments may operate based on at least a portion of signals, output from the reset circuits 211G and 212G included therein, and signals output from the external reset circuit 150.

As a result, the system-on-chip 100J may stably control a power-on reset operation of each of the plurality of dies 111J and 112J.

According to some example embodiments, the system-on-chip 100J may stably control the power for the operation of each of the plurality of dies 111J and 112J through the above-described configurations.

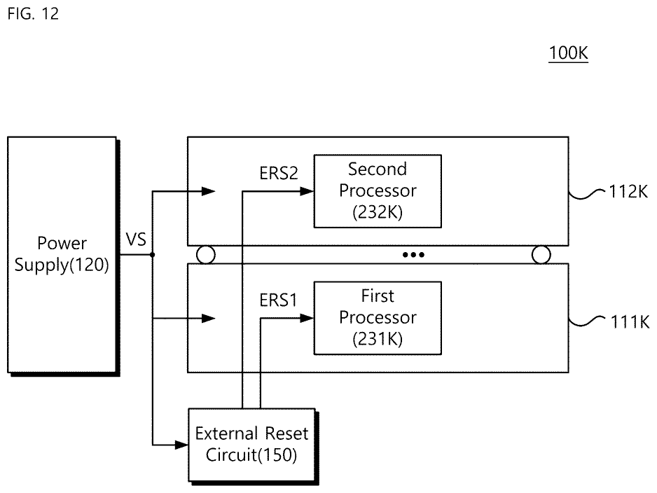

FIG. 12 is a diagram illustrating a system-on-chip including an external reset circuit outputting an external reset signal based on a supply voltage according to some example embodiments.

Referring to FIG. 12, a system-on-chip 100K according to some example embodiments may include a plurality of dies 111K and 112K and an external reset circuit 150.

The system-on-chip 100K illustrated in FIG. 12 may be understood as an example of the system-on-chip 100 illustrated in FIG. 1. Therefore, the same or substantially the same components are denoted by the same or substantially the same reference numerals, and redundant descriptions are omitted to avoid repetition.

According to some example embodiments, the system-on-chip 100K may include an external reset circuit 150 connected between a power supply 120 and the plurality of dies 111K and 112K.

For example, the external reset circuit 150 may output a first external reset signal ERS1 and a second external reset signal ERS2 in response to a supply voltage VS transmitted, transferred, or sent from the power supply 120.

According to some example embodiments, the external reset circuit 150 may output a first external reset signal ERS1 and a second external reset signal ERS2 in response to the supply voltage VS being stabilized.

For example, the external reset circuit 150 may output the first external reset signal ERS1 and the second external reset signal ERS2 in response to a change amount of the supply voltage VS being less than a threshold value for a unit time.

In some example embodiments, the plurality of dies 111K and 112K may operate in response to the external reset signals ERS1 and ERS2, respectively.

According to some example embodiments, the first processor 231K may operate the first die 111K in response to the first external reset signal ERS1. For example, the first processor 231K may operate the first die 111K in response to a first external reset signal ERS1 having a high level.

For example, the first processor 231K may reset power for an operation of the first die 111K in response to the first external reset signal ERS1. Thus, the first processor 231K may operate the first die 111K.

For example, the first processor 231K may operate at least a portion of a plurality of first IP blocks (for example, 131 of FIG. 1), included in the first die 111K, using the supply voltage VS in response to the first external reset signal ERS1.

According to some example embodiments, the second processor 232K may operate the second die 112K in response to the second external reset signal ERS2. For example, the second processor 232K may operate the second die 112K in response to a second external reset signal ERS2 having a high level.

For example, the second processor 232K may reset power for an operation of the second die 112K in response to the second external reset signal ERS2. Thus, the second processor 232K may operate the second die 112K.

For example, the second processor 232K may operate at least a portion of a plurality of second IP blocks (for example, 132 of FIG. 1), included in the second die 112K, using the supply voltage VS in response to the second external reset signal ERS2.

Referring to the above-described configurations, the external reset circuit 150 according to some example embodiments may output different external reset signals ERS1 and ERS2 for the plurality of dies 111K and 112K using the supply voltage VS.

As a result, the system-on-chip 100K according to some example embodiments may independently and stably control a power-on reset operation for each of the plurality of dies 111K and 112K.

Furthermore, in some example embodiments the system-on-chip 100K may stably control the power for the operation of each of the plurality of dies 111K and 112K through the above-described configurations.

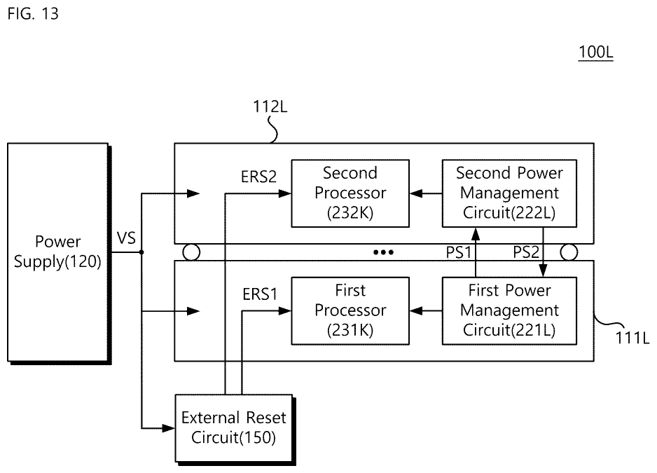

FIG. 13 is a diagram illustrating a system-on-chip, including an external reset circuit according to some example embodiments, in which each die includes a power management circuit.

Referring to FIG. 13, a system-on-chip 100L according to some example embodiments may include a first die 111L and a second die 112L. The first die 111L and the second die 112L may include processors 231K and 232K and power management circuits 221L and 222L, respectively. For example, the first die 111L may include a first processor 231K and a first power management circuit 221L, and the second die 112L may include a second processor 232K and a second power management circuit 222L.

The system-on-chip 100L illustrated in FIG. 13 may be understood as an example that further includes power management circuits 221L and 222L, in addition to the configuration of the system-on-chip 100K illustrated in FIG. 12. Therefore, the same or substantially the same components are denoted by the same or substantially the same reference numerals, and redundant descriptions are omitted to avoid repetition.

According to some example embodiments, the first die 111L may further include the first power management circuit 221L.

For example, the first power management circuit 221L may transmit, transfer, or sned first power information PS1 to the second die 112L. In some example embodiments, the first power management circuit 221L may obtain second power information PS2 from the second die 112L.

In some example embodiments, the second die 112L may further include the second power management circuit 222L.

For example, the second power management circuit 222L may transmit, transfer, or send second power information PS2 to the first die 111L. In some example embodiments, the second power management circuit 222L may acquire, obtain, or receive first power information PS1 from the first die 111L.

According to some example embodiments, the first processor 231K may determine whether the second die 112L is operating based on second power information PS2.

Furthermore, in some example embodiments, the first processor 231K may operate based on whether the second die 112L is operating while the first external reset signal ERS1 is input.

For example, the first processor 231K may operate based on whether the second die 112L is operating when an interaction (for example, data exchange) between the first die 111L and the second die 112L is required.

For example, when receiving an execution request for an application that requires data exchange between the first die 111L and the second die 112L, the first processor 231K may determine whether the second die 112L is operating, based on the second power information PS2.

Furthermore, in some example embodiments, when the second die 112L is operating, the first processor 231K may control an operation of the first die 111L based on the data signal received from the second die 112L to execute an application that has received an execution request.

According to some example embodiments, the first processor 231K may operate the first die 111L using the supply voltage VS transmitted, transferred, or sent from a power supply 120.

In some example embodiments, the second processor 232K may determine whether the first die 111L is operating based on the first power information PS1.

Furthermore, in some example embodiments, the second processor 232K may operate based on whether the first die 111L is operating while the second reset signal RS2 is output.

For example, the second processor 232K may operate based on whether the first die 111L is operating when an interaction (for example, data exchange) between the first die 111L and the second die 112L is required.

For example, when receiving an execution request for an application that requires data exchange between the first die 111L and the second die 112L, the second processor 232K may determine whether the first die 111L is operating, based on the first power information PS1.

Furthermore, in some example embodiments, when the first die 111L is operating, the second processor 232K may control an operation of the second die 112L based on a data signal, received from the first die 111L, to execute an application that has received an execution request.

According to some example embodiments, the second processor 232K may operate the second die 112L using the supply voltage VS transmitted, transferred, or sent from the power supply 120.

Referring to the above-described configurations according to some example embodiments, the first processor 231K and the second processor 232K may determine whether another die is operating, based on the power information PS1 and PS2 received through the power management circuit 221L and 222L

Furthermore, in some example embodiments, each of the first processor 231K and the second processor 232K may perform an operation of requesting the first die 111L and the second die 112L to operate together in response to the other die being operating.

As a result, the system-on-chip 100L may reduce the time it takes to reset power of the plurality of dies 111L and 112L and operate the plurality of dies 111L and 112L when an interaction between the plurality of dies 111L and 112L is required.

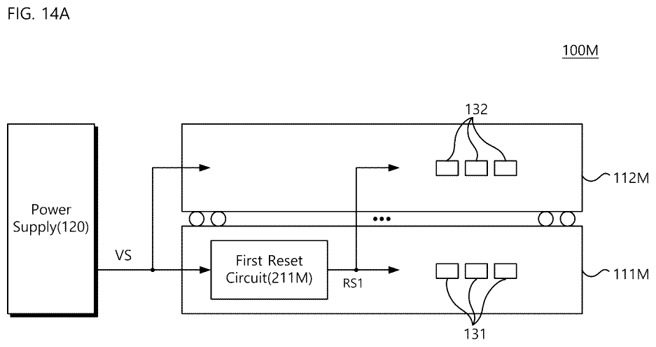

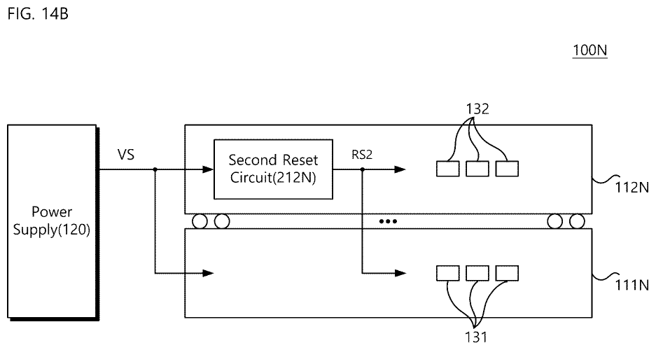

FIG. 14A is a diagram illustrating a configuration in which a first die and a second die according to some example embodiments operate in response to a first reset signal generated from the first die. FIG. 14B is a diagram illustrating a configuration in which a first die and a second die according to some example embodiments operate in response to a second reset signal generated from the second die.

Referring to FIG. 14A, a system-on-chip 100M according to some example embodiments may include a first die 111M and a second die 112M. The first die 111M may include a first reset circuit 211M.

The system-on-chip 100M illustrated in FIG. 14A may be understood as an example of the system-on-chip 100 illustrated in FIG. 1.

According to some example embodiments, the first die 111M may include a first reset circuit 211M outputting a first reset signal RS1 based on a supply voltage VS.

For example, the first reset circuit 211M may output the first reset signal RS1 based on the supply voltage VS transmitted, transferred, or sent from a power supply 120.

The first reset signal RS1 may be understood as a signal for resetting power supplied to the first die 111M to turn on the first die 111M.

According to some example embodiments, the first die 111M may operate in response to the first reset signal RS1.

For example, the first die 111M may operate using the supply voltage VS in response to the first reset signal RS1.

For example, the first die 111M may operate at least a portion of a plurality of first IP blocks 131 using the supply voltage VS in response to the first reset signal RS1.

In some example embodiments, the first die 111M may transmit, transfer, or send the first reset signal RS1 to the second die 112M. For example, the first die 111M may transmit, transfer, or send the first reset signal RS1, output from the first reset circuit 211M, to the second die 112M.

For example, the first die 111M may transmit, transfer, or send the first reset signal RS1 to the second die 112M through a through-silicon via (TSV) formed to penetrate through at least a portion of the first die 111M and the second die 112M.

According to some example embodiments, the second die 112M may operate in response to the first reset signal RS1.

For example, the second die 112M may operate using the supply voltage VS in response to the first reset signal RS1 received from the first die 111M.

For example, the second die 112M may operate at least a portion of a plurality of second IP blocks 132 using the supply voltage VS in response to the first reset signal RS1.

Referring to FIG. 14B, a system-on-chip 100N according to some example embodiments may include a first die 111N and a second die 112N. The second die 112N may include a second reset circuit 212N.

The system-on-chip 100N illustrated in FIG. 14B may be understood as an example of the system-on-chip 100 illustrated in FIG. 1.

According to some example embodiments, the second die 112N may include a second reset circuit 212N outputting a second reset signal RS2 based on a supply voltage VS.

For example, the second reset circuit 212N may output the second reset signal RS2 based on the supply voltage VS transmitted, transferred, or sent from a power supply 120.

The second reset signal RS2 may be understood as a signal for resetting power supplied to the second die 112N to turn on the second die 112N.

According to some example embodiments, the second die 112N may operate in response to the second reset signal RS2.

For example, the second die 112N may operate using the supply voltage VS in response to the second reset signal RS2.

For example, the second die 112N may operate at least a portion of a plurality of second IP blocks 132 using the supply voltage VS in response to the second reset signal RS2.

In some example embodiments, the second die 112N may transmit, transfer, or send the second reset signal RS2 to the first die 111N. For example, the second die 112N may transmit, transfer, or send the second reset signal RS2, output from the second reset circuit 212N, to the first die 111N.

For example, the second die 112N may transmit, transfer, or send the second reset signal RS2 to the first die 111N through a through-silicon via (TSV) formed to penetrate through at least a portion of the first die 111N and the second die 112N.

According to some example embodiments, the first die 111N may operate in response to the second reset signal RS2.

For example, the first die 111N may operate using the supply voltage VS in response to the second reset signal RS2 received from the second die 112N.

For example, the first die 111N may operate at least a portion of a plurality of first IP blocks 131 using the supply voltage VS in response to the second reset signal RS2.

Referring to the above-described configurations, each of the system-on-chips 100M and 100N according to some example embodiments may reset power for an operation of the plurality of dies using a reset signal output from a single reset circuit.

As a result, the system-on-chips 100M and 100N may operate the plurality of dies.

The above-described configurations according to some example embodiments may allow the system-on-chips 100M and 100N to significantly reduce an area and costs required to implement a circuit resetting the power of the plurality of dies to operate the plurality of dies.

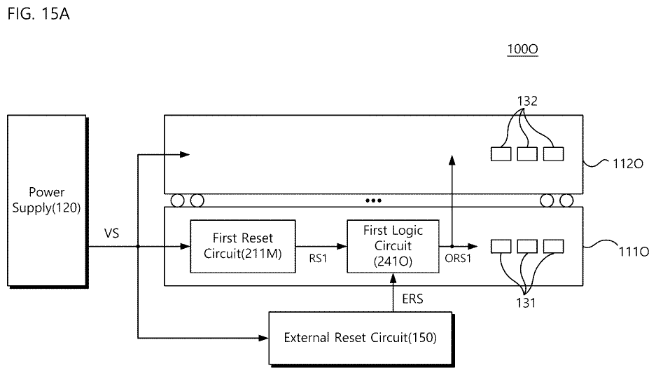

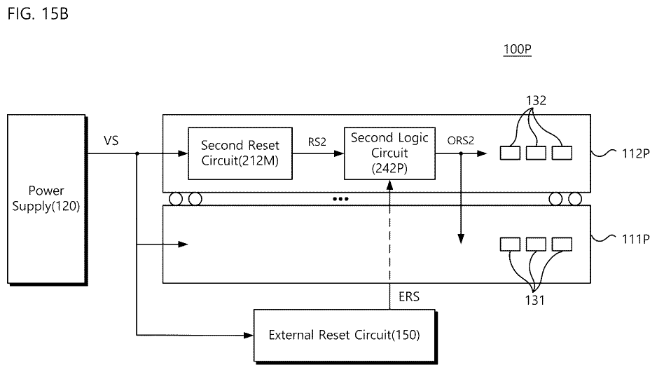

FIG. 15A is a diagram illustrating a configuration in which a first die and a second die according to some example embodiments operate in response to a first output reset signal output from a first logic circuit. FIG. 15B is a diagram illustrating a configuration in which a first die and a second die according to some example embodiments operate in response to a second output reset signal output from a second logic circuit.

Referring to FIG. 15A, a system-on-chip 1000 according to some example embodiments may include a first die 1110, a second die 1120, and an external reset circuit 150. The first die 1110 may include a first reset circuit 211M and a first logic circuit 2410.

The system-on-chip 1000 illustrated in FIG. 15A may be understood as an example that further includes a first logic circuit 2410 and an external reset circuit 150, in addition to the configuration of the system-on-chip 100M illustrated in FIG. 14A.

Therefore, the same or substantially the same components are denoted by the same or substantially the same reference numerals, and redundant descriptions are omitted to avoid repetition.

According to some example embodiments, the external reset circuit 150 may include an external reset signal ERS output based on a supply voltage VS transmitted, transferred, or sent from a power supply 120. For example, the external reset circuit 150 may output the external reset signal ERS based on the supply voltage VS transmitted, transferred, or sent from the power supply 120.

The first die 1110 may include a first logic circuit 2410 outputting a first output reset signal ORS1 based on at least one of a first reset signal RS1 and the external reset signal ERS.

For example, the first logic circuit 2410 may output the first output reset signal ORS1 through a logical operation between the first reset signal RS1 and the external reset signal ERS.

According to some example embodiments, the first logic circuit 2410 may include an AND gate. Accordingly, the first logic circuit 2410 may output the first output reset signal ORS1 as a result of a logical AND operation between the first reset signal RS1 and the external reset signal ERS.

Furthermore, in some example embodiments, the first die 1110 may operate in response to the first reset signal RS1.

For example, the first die 1110 may operate using the supply voltage VS in response to the first output reset signal ORS1.

For example, the first die 1110 may operate at least a portion of a plurality of first IP blocks 131 using the supply voltage VS in response to the first output reset signal ORS1.

In some example embodiments, the first die 1110 may transmit, transfer, or send the first output reset signal ORS1 to the second die 1120. For example, the first die 1110 may transmit, transfer, or send the first output reset signal ORS1, output from the first logic circuit 2410, to the second die 1120.

For example, the first die 1110 may transmit, transfer, or send the first output reset signal ORS1 to the second die 1120 through a through-silicon via (TSV) formed to penetrate through at least a portion of the first die 1110 and the second die 1120.

According to some example embodiments, the second die 1120 may operate in response to the first output reset signal ORS1.

For example, the second die 1120 may operate using the supply voltage VS in response to the first output reset signal ORS1 received from the first die 1110.

For example, the second die 1120 may operate at least a portion of a plurality of second IP blocks 132 using the supply voltage VS in response to the first output reset signal ORS1.

Referring to FIG. 15B, a system-on-chip 100P according to some example embodiments may include a first die 111P, a second die 112P, and an external reset circuit 150. The second die 112P may include a second reset circuit 212M and a second logic circuit 242P.

The system-on-chip 100P illustrated in FIG. 15B may be understood as an example that further includes a second logic circuit 242P and an external reset circuit 150, in addition to the configuration of the system-on-chip 100N illustrated in FIG. 14B.

Therefore, the same or substantially the same components are denoted by the same or substantially the same reference numerals, and redundant descriptions are omitted to avoid repetition.

The second die 112P may include a second logic circuit 242P outputting a second output reset signal ORS2 based on at least a portion of a second reset signal RS2 and an external reset signal ERS.

For example, the second logic circuit 242P may output the second output reset signal ORS2 through a logical operation between the second reset signal RS2 and the external reset signal ERS.

According to some example embodiments, the second logic circuit 242P may include an AND gate. Therefore, the second logic circuit 242P may output the second output reset signal ORS2 as a result of a logical AND operation between the second reset signal RS2 and the external reset signal ERS.

The second die 112P may operate in response to the second reset signal RS2.

For example, the second die 112P may operate using a supply voltage VS in response to the second output reset signal ORS2.

For example, the second die 112P may operate at least a portion of a plurality of second IP blocks 132 using the supply voltage VS in response to the second output reset signal ORS2.

In some example embodiments, the second die 112P may transmit, transfer, or send the second output reset signal ORS2 to the first die 111P. For example, the second die 112P may transmit, transfer, or send the second output reset signal ORS2, output from the second logic circuit 242P, to the first die 111P.

For example, the second die 112P may transmit, transfer, or send the second output reset signal ORS2 to the first die 111P through a through-silicon via (TSV) formed to penetrate through at least a portion of the first die 111P and the second die 112P.

According to some example embodiments, the first die 111P may operate in response to the second output reset signal ORS2.

For example, the first die 111P may operate using the supply voltage VS in response to the second output reset signal ORS2 received from the second die 112P.

For example, the first die 111P may operate at least a portion of a plurality of first IP blocks 131 using the supply voltage VS in response to the second output reset signal ORS2.

Referring to the above-described configurations, the system-on-chips 1000 and 100P according to some example embodiments may reset power for an operation of the plurality of dies using a reset signal output from a single reset circuit. As a result, the system-on-chips 1000 and 100P may operate the plurality of dies.

The above-described configurations may allow the system-on-chips 1000 and 100P to significantly reduce an area and costs required to implement a circuit for resetting power of the plurality of dies and operating the plurality of devices.

Referring to the above-described configurations, the system-on-chips 1000 and 100P according to some example embodiments may use reset signals, respectively output from an internal reset circuit and an external reset circuit 150, to reset power of each of the reset signals by using a logic circuit.

As a result, the system-on-chips 1000 and 100P may improve stability of a power-on reset operation for each of the plurality of dies.

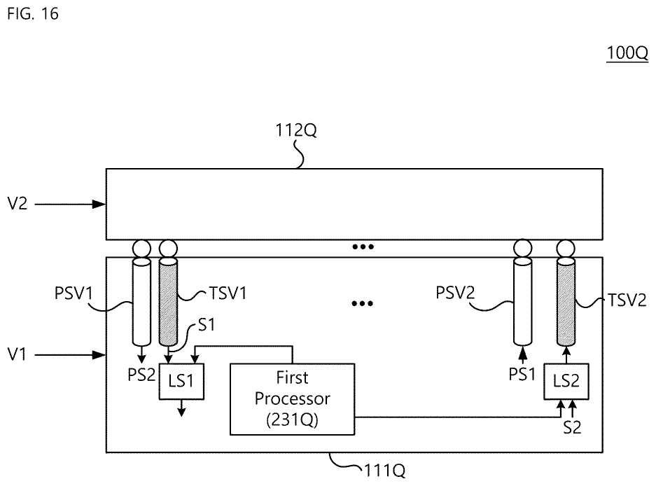

FIG. 16 is a diagram illustrating a system-on-chip in which a first die according to some example embodiments further includes a plurality of level shifters.

Referring to FIG. 16, a system-on-chip 100Q according to some example embodiments may include a first die 111Q and a second die 112Q.

The system-on-chip 100Q illustrated in FIG. 16 may be understood as an example of the system-on-chip 100 illustrated in FIG. 1. Therefore, the same or substantially the same components are denoted by the same or substantially the same reference numerals, and redundant descriptions are omitted to avoid repetition.

The system-on-chip 100Q may include a plurality of through-silicon vias (TSVs) TSV1 and TSV1 and a plurality of power vias PSV1 and PSV2 formed to penetrate through at least a portion of the first die 111Q and the second die 112Q.

Each of the plurality of TSVs, e.g., TSV1 and TSV1, may be referred to as a path through which the first die 111Q and the second die 112Q exchange signals S1 and S2. In some example embodiments, each of the plurality of power vias PSV1 and PSV2 may be referred to as a path through which the first die 111Q and the second die 112Q exchange power information PS1 and PS2.

In some example embodiments, the first die 111Q may include level shifters LS1 and LS2, respectively connected to the plurality of TSVs TSV1 and TSV2.

According to some example embodiments, the system-on-chip 100Q may include a first TSV TSV1 and a second TSV TSV2 formed to penetrate through at least a portion of the first die 111Q and the second die 112Q.

The first die 111Q may include a first level shifter LS1 connected to the first TSV TSV1.

For example, the first die 111Q may include a first level shifter LS1 receiving a first signal S1 transmitted, transferred, or sent from the second die 112Q through the first TSV TSV1.

According to some example embodiments, a first processor 231Q may control an operation of the first level shifter LS1 based on the second power information PS2 transmitted, transferred, or sent through the first power via PSV1.

For example, the first processor 231Q may determine whether the second die 112Q is operating, based on the second power information PS2.

According to some example embodiments, when the second die 112Q is operating, the first processor 231Q may control the first level shifter LS1 to adjust a power level of the first signal S1.

For example, the first signal S1 may be understood as a data signal transmitted, transferred, or sent from the second die 112Q to the first die 111Q, but example embodiments are not limited thereto.

For example, when the second die 112Q is operating, the first processor 231Q may adjust the power level of the first signal S1 through the first level shifter LS1 based on power levels of the first voltage V1 and the second voltage V2.

For example, when the second die 112Q is operating and the first voltage V1 has a first power level and the second voltage V2 has a second power level, the first processor 231Q may control the first level shifter LS1 such that the first signal S1 has a power level corresponding to the first power level.

For example, each the first and second power levels may be understood as having absolute values. For example, each of the first and second power levels may be understood as representing a range of power magnitude.

In some example embodiments, the first die 111Q may include a second level shifter LS2 connected to the second TSV TSV2.

For example, the first die 111Q may include a second level shifter LS2 transmitting, transferring, or sending the second signal S2 to the second die 112Q through the second TSV TSV2.

According to some example embodiments, when the first die 111Q and the second die 112Q are operating, the second level shifter LS2 may be controlled to adjust the power level of the second signal S2.

For example, the second signal S2 may be understood as a data signal transmitted from the first die 111Q to the second die 112Q, but example embodiments are not limited thereto.

For example, when the first die 111Q and the second die 112Q are operating, the first processor 231Q may adjust the power level of the second signal S2 through the second level shifter LS2 based on the power levels of the first voltage V1 and the second voltage V2.

For example, when the second die 112Q is operating and the first voltage V1 has a first power level and the second voltage V2 has a second power level, the first processor 231Q may control the second level shifter LS2 such that the second signal S2 has a power level corresponding to the second power level.

Referring to the above-described configurations according to some example embodiments, the system-on-chip 100Q may adjust the power levels of the signals S1 and S2 exchanged between the first die 111Q and the second die 112Q to correspond to a transmitted, transferred, or sent power level of a die using the level shifters LS1 and LS2.

As a result, the system-on-chip 100Q may significantly reduce leakage current that may be generated during signal exchange between the plurality of dies 111Q and 112Q.

According to some example embodiments, when the second die 112Q is not operating, the first processor 231Q may control the first level shifter LS1 such that the first level shifter LS1 outputs a predetermined, or alternatively desired value.

For example, when the second die 112Q is not operating, the first processor 231Q may control the first level shifter LS1 such that the first level shifter LS1 outputs a predetermined, or alternatively desired value regardless of a signal transmitted, transferred, or sent from the second die 112Q.

For example, when an unknown signal from the non-operating second die 112Q is introduced into the first die 111Q, the first processor 231Q may control the first level shifter LS1 such that the first level shifter LS1 outputs a predetermined value of “1.”

In some example embodiments, the first processor 231Q may control the second level shifter LS2 such that the second level shifter LS2 outputs a predetermined value when the first die 111Q is not operating and the second die 112Q is operating.

For example, if the second die 112Q is operating and the first die 111Q is not operating, the first processor 231Q may control the second level shifter LS2 such that the second level shifter LS2 outputs a predetermined value of “0.”

Referring to the above-described configurations, the first processor 231Q according to some example embodiments may control the first level shifter LS1 such that an unknown signal is not transmitted from a non-operating die to an operating die when only one of the plurality of dies 111Q and 112Q is operating.

As a result, the system-on-chip 100Q may significantly reduce the likelihood of a malfunction in an operating die caused by an unknown signal introduced into the operating die from a non-operating die among the plurality of dies 111Q and 112Q.

As described above, the system-on-chip 100 according to some example embodiments may output different reset signals RS1 and RS2 for each of the plurality of dies 111 and 112 using the reset circuits 211 and 212, respectively provided within the plurality of dies 111 and 112.

As a result, the system-on-chip 100 according to some example embodiments may independently and reliably control a power-on reset operation on each of the plurality of dies 111 and 112.

Furthermore, the system-on-chip 100 may reliably control power for the operation of each of the plurality of dies 111 and 112.

According to some example embodiments, the first processor 231 and the second processor 232 may determine whether another die is operating based on the power information PS1 and PS2 received through the power management circuit 221 and 222.

Furthermore, in some example embodiments each of the first and second processors 231 and 232 may perform an operation that requires an interaction between the first die 111 and the second die 112 in response to another die being operating.

As a result, the system-on-chip 100 may reduce the time it takes to turn on (or operate) the power of the plurality of dies 111 and 112 when an interaction between the plurality of dies 111 and 112 is required.

In some example embodiments, the system-on-chip 100 may reliably control the power for the operation of each of the plurality of dies 111 and 112 when an interaction between the plurality of dies 111 and 112 is required.

According to some example embodiments, the system-on-chip 100 may adjust power levels of the signals S1 and S2 exchanged between the first die 111 and the second die 112 to correspond to a transmitted, transferred, or sent power level of a die using the level shifters LS1 and LS2.

As a result, the system-on-chip 100 may significantly reduce leakage current that may be generated during signal exchange between the plurality of dies 111 and 112.

According to some example embodiments, the first processor 231 may control the first level shifter LS1 such that an unknown signal is not transmitted from a non-operating die to an operating die when only one of the plurality of dies 111 and 112 is operating.

As a result, the system-on-chip 100 may significantly reduce the likelihood of a malfunction in the operating die caused by an unknown signal introduced from the non-operating die to the operating die among the plurality of dies 111 and 112.

As set forth above, a system-on-chip according to some example embodiments may stably control power for the operation of each of a plurality of dies.

While some example embodiments have been shown and described above, it will be apparent to those skilled in the art that modifications and variations could be made without departing from the scope of the present inventive concepts as defined by the appended claims.

What is claimed is:

1. A system-on-chip (SoC), comprising:
a first die; and
a second die adjacent to a surface of the first die, the second die connected to the first die,
the first die including a first reset circuit configured to output a first reset signal to operate the first die based on a first voltage received from a power supply, and
the second die including a second reset circuit configured to output a second reset signal to operate the second die based on a second voltage received from the power supply.

2. The system-on-chip of claim 1, wherein
the first die comprises a first power management circuit configured to send first power information of the first die to the second die, and receive second power information of the second die from the second die, and
the second die comprises a second power management circuit configured to send the second power information of the second die to the first die, and receive the first power information of the first die from the first die.

3. The system-on-chip of claim 2, wherein
the first die comprises a first processor configured to operate the first die in response to the first reset signal, and
the first processor is configured to,
determine whether the second die is operating based on the second power information; and
control an operation of the first die, based on a data signal received from the second die, when the second die is operating.

4. The system-on-chip of claim 3, wherein
the first processor is configured to output a first operation request to operate the second die to at least one of the power supply and the second reset circuit when the second die is not operating.

5. The system-on-chip of claim 3, wherein
the second die comprises a second processor configured to operate the second die in response to the second reset signal, and
the second processor is configured to,
determine whether the first die is operating based on the first power information, and
control an operation of the second die based on a data signal received from the first die when the first die is operating.

6. The system-on-chip of claim 5, wherein
an external reset circuit is configured to output an external first reset signal based on the first voltage received from the power supply,
the first die further comprises a first logic circuit configured to output a first output reset signal based on at least a portion of the first reset signal and the first external reset signal, and
the first processor is configured to operate the first die in response to the first output reset signal.

7. The system-on-chip of claim 6, wherein
the first logic circuit is configured to output the first output reset signal through an AND operation between the first reset signal and the first external reset signal.

8. The system-on-chip of claim 6, wherein
the external reset circuit is configured to output an external second reset signal based on the second voltage,
the second die further comprises a second logic circuit configured to output a second output reset signal based on at least a portion of the second reset signal and the second external reset signal, and
the second processor is configured to operate the second die in response to the second output reset signal.

9. The system-on-chip of claim 1, wherein
the second die is connected to the first die through a plurality of pads on the surface of the first die.

10. The system-on-chip of claim 3, wherein
the first die and the second die are connected through a plurality of through-silicon vias (TSVs),
the first die comprises a first level shifter configured to receive a first signal sent from the second die through a first through-silicon via, and
the first processor, based on the second power information, is configured to,
control the first level shifter such that the first signal has a power level corresponding to a first power level of the first voltage when the second die is operating; and
control the first level shifter such that the first level shifter outputs a value when the second die is not operating.

11. A system-on-chip (SoC), comprising:
a first die;
a second die adjacent to a surface of the first die, the second die connected to the first die through a plurality of pads on the surface of the first die; and
an external reset circuit configured to output a first reset signal based on a first voltage received from a power supply, and output a second reset signal based on a second voltage received from the power supply,
the first die configured to operate with the first voltage in response to the first reset signal, and
the second die configured to operate with the second voltage in response to the second reset signal.

12. The system-on-chip of claim 11, wherein
the first die comprises,
a first processor configured to operate the first die in response to the first reset signal; and
a first power management circuit configured to send first power information of the first die to the second die and receive second power information of the second die from the second die, and
the first processor is configured to,
determine whether the second die is operating based on the second power information; and
control the operation of the first die based on a data signal received from the second die when the second die is operating.

13. The system-on-chip of claim 12, wherein
the first processor is configured to output a first operation request to operate the second die to at least a portion of the power supply and the external reset circuit when the second die is not operating.

14. The system-on-chip of claim 12, wherein
the second die comprises,
a second processor configured to operate the second die in response to the second reset signal; and
a second power management circuit configured to receive the first power information from the first die and send the second power information to the first die, and
the second processor is configured to,
determine whether the first die is operating based on the first power information; and
control an operation of the second die based on a data signal received from the first die when the first die is operating.

15. The system-on-chip of claim 12, wherein
the first die and the second die are connected through a plurality of through-silicon vias (TSVs),
the first die comprises a first level shifter configured to receive a first signal sent from the second die through a first through-silicon via, and
the first processor, based on the second power information, is configured to,
control the first level shifter such that the first signal has a power level corresponding to a first power level of the first voltage when the second die is operating; and
control the first level shifter such that the first level shifter outputs a value when the second die is not operating.

16. A system-on-chip (SoC), comprising:
a first die; and
a second die adjacent to a surface of the first die, the second die connected to the first die through a plurality of pads on the surface of the first die,
the first die including a first reset circuit configured to output a first reset signal to operate the first die based on a supply voltage received from a power supply, and
the second die including a second reset circuit configured to output a second reset signal, different from the first reset signal, to operate the second die based on the supply voltage.

17. The system-on-chip of claim 16, wherein
the first die comprises a first power management circuit configured to send first power information of the first die to the second die, and receive second power information of the second die from the second die, and
the second die comprises a second power management circuit configured to send the second power information of the second die to the first die, and receive the first power information of the first die from the first die.

18. The system-on-chip of claim 17, wherein
the first die comprises a first processor configured to operate the first die in response to the first reset signal, and
the first processor is configured to,
determine whether the second die is operating based on the second power information; and
control an operation of the first die based on a data signal received from the second die when the second die is operating.

19. The system-on-chip of claim 18, further comprising:
an external reset circuit configured to output an external reset signal based on the supply voltage,
the first die further including a first logic circuit configured to output a first output reset signal through a logical AND operation between the first reset signal and the external reset signal, and
the first processor configured to operate the first die in response to the first output reset signal.

20. The system-on-chip of claim 19, wherein
the second die further comprises,
a second processor configured to control an operation of the second die; and
a second logic circuit configured to output a second output reset signal through a logical AND operation between the second reset signal and the external reset signal, and
the second processor is configured to operate the second die in response to the second output reset signal.
